(19) United States
(12) Patent Application Publication
(10) Pub. No.: US 2026/0015719 A1
(43) Pub. Date: Jan. 15, 2026

(54) METHOD AND APPARATUS FOR FORMING MOLYBDENUM METAL FILM

(71) Applicant: Tokyo Electron Limited, Tokyo (JP)

(72) Inventors: Daisuke HOJO, Nirasaki City (JP); Yuka GOTO, Nirasaki City (JP); Kazunaga ONO, Nirasaki City (JP); Satoshi WAKABAYASHI, Nirasaki City (JP)

(21) Appl. No.: 19/261,691

(22) Filed: Jul. 7, 2025

(30) Foreign Application Priority Data
Jul. 10, 2024 (JP) 2024-111184

(51) Int. Cl. C23C 16/455; C23C 14/18; C23C 16/02; C23C 16/08; C23C 16/52

(52) U.S. Cl. CPC C23C 16/45525; C23C 14/18; C23C 16/0281; C23C 16/08; C23C 16/52

(57) ABSTRACT

A method of forming a molybdenum metal film on a substrate includes forming a tungsten metal underlying film on the substrate, and forming the molybdenum metal film on the tungsten metal underlying film.

### CROSS-REFERENCE TO RELATED APPLICATION

This application is based upon and claims the benefit of priority from Japanese Patent Application No. 2024-111184, filed on Jul. 10, 2024, the entire contents of which are incorporated herein by reference.

### TECHNICAL FIELD

The present disclosure relates to a method and an apparatus for forming a molybdenum metal film.

### BACKGROUND

In a semiconductor manufacturing apparatus, copper has been used as a wiring material in the related art. However, as conductor devices have become miniaturized, a problem of increased specific resistance has been arising in such a copper wiring due to a fine line effect. For this reason, replacing copper with a wiring material, in which the fine line effect is more difficult to occur as compared with copper, has been under consideration.

As a method of forming a low-resistance thin film, Patent Document 1 discloses a technique of forming a low-resistance tungsten film by stacking a tungsten liner layer and a tungsten film one above another in electronic device manufacturing.

### PRIOR ART DOCUMENTS

### Patent Documents

Patent Document 1: Japanese Patent Application Publication No. 2023-516859

### SUMMARY

According to an embodiment of the present disclosure, a method of forming a molybdenum metal film on a substrate includes forming a tungsten metal underlying film on the substrate, and forming the molybdenum metal film on the tungsten metal underlying film.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIGS. 1A to 1C are a first process diagram illustrating a first embodiment of a method of forming a molybdenum metal film.

FIG. 2 is a first characteristic graph illustrating a relationship between a film thickness and a specific resistance of a molybdenum film.

FIG. 3 is a second characteristic graph illustrating the relationship between the film thicknesses and the specific resistance of the molybdenum film.

FIG. 4 is a first crystal grain map of the molybdenum film.

FIG. 5 is a second crystal grain map of the molybdenum film.

FIG. 6 is a crystal grain map of a tungsten film.

FIG. 7 is a first XRD crystal structure analysis result of the tungsten film.

FIG. 8 is a third characteristic graph illustrating a relationship between a film thickness of a stacked film of the tungsten film and the molybdenum film and a specific resistance of the stacked film.

FIG. 9 is a fourth characteristic graph illustrating the relationship between the film thicknesses of the stacked film of the tungsten film and the molybdenum film and the specific resistance of the stacked film.

FIG. 10 is a fifth characteristic graph illustrating the relationship between the film thicknesses of the stacked film of the tungsten film and the molybdenum film and the specific resistance of the stacked film.

FIGS. 11A to 11C are a second process diagram illustrating a second embodiment of a method of forming a molybdenum metal film.

FIG. 12 is a sixth characteristic graph illustrating a relationship between a film thickness and a specific resistance of the molybdenum film.

FIG. 13 is a seventh characteristic graph illustrating the relationship between the film thicknesses and the specific resistance of the molybdenum film.

FIG. 14 is a second XRD crystal structure analysis result of a tungsten film.

FIG. 15 is an eighth characteristic graph illustrating the relationship between the film thicknesses of the stacked film of the tungsten film and the molybdenum film and the specific resistance of the stacked film.

FIG. 16 is a third process diagram illustrating an operation of forming a tungsten film and a molybdenum film.

FIG. 17 is a plan view illustrating an exemplary configuration of a film forming apparatus which forms a molybdenum film.

FIG. 18 is a longitudinal side view illustrating an exemplary configuration of a first processing module which forms a tungsten film.

FIG. 19 is a longitudinal side view illustrating an exemplary configuration of a second processing module which forms the molybdenum film.

FIG. 20 is a fourth process diagram illustrating an operation of forming the tungsten film and the molybdenum film.

FIG. 21 is a plan view illustrating another exemplary configuration of the film forming apparatus which forms the molybdenum film.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

The present inventors have made studies on using molybdenum (Mo) as a wiring material substituting for copper (Cu) in a semiconductor device. Mo is a material that has more difficulty generating a fine line effect as compared with Cu or tungsten (W). Even if a line width of an electrode becomes miniaturized, Mo is less susceptible to the fine line effect and thus, suppression of an increase in specific resistance can be expected. On the other hand, W tends to have a smaller grain size than Mo. In general, the grain size and the specific resistance have a relationship as follows: as the grain size increases, a crystal gain boundary also becomes smaller, which leads to a decrease in the specific resistance. Therefore, in the case of Mo, the grain size may be set as large as possible to suppress an increase in the specific resistance.

For example, when Mo has a film thickness of 10 nm or more, the specific resistance thereof is substantially the same as that of W. However, as a film of Mo becomes thinner, influence due to a small grain size is increased. Thus, a technique for reducing the specific resistance of Mo by increasing the grain size of Mo even if the Mo film is thin is under consideration. In addition, the present inventors focused on the fact that the grain size of Mo is increased by using an underlying film formed below the Mo film and found that the grain size of Mo may be increased by using, as the underlying layer, W having a grain size larger than that of Mo.

As described above, the present disclosure provides forming a metal underlying film made of tungsten (W) on a semiconductor wafer (hereinafter, referred to as a “wafer”) which is a substrate, and forming a molybdenum metal film on the metal underlying film.

### First Embodiment

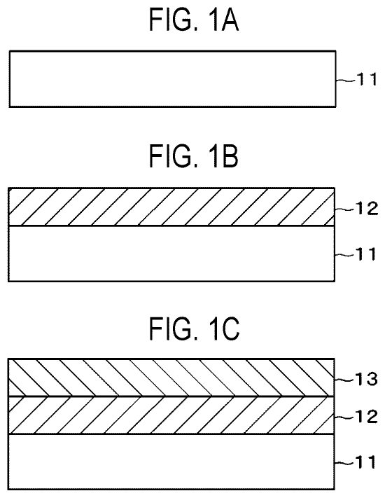

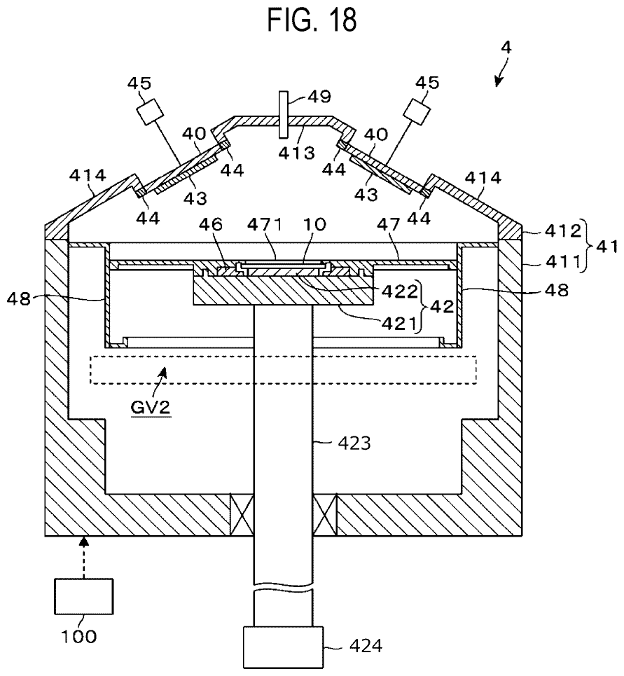

Next, a method of forming a Mo metal film according to a first embodiment of the present disclosure will be described. FIG. 1A shows a silicon oxide film (SiO₂ film) 11 formed on a wafer 10 (see FIG. 18 to be described later) which is a substrate. The SiO₂ film has a recess (not illustrated) constituting a trench, a via hole, or the like.

In addition, as illustrated in FIG. 1B, an operation of forming a tungsten metal underlying film 12 on the wafer 10 having the SiO₂ film 11 formed thereon is performed.

The tungsten metal underlying film 12 may be formed by, for example, a sputtering method, a deposition method, an atomic layer deposition (ALD) method, or a chemical vapor deposition (CVD) method. The tungsten metal underlying film 12 may be formed to entirely cover, for example, a bottom surface and a side surface of the recess, but may be formed only on the bottom surface or the side surface of the recess formed in the SiO₂ film 11. A film thickness of the tungsten metal underlying film 12 is set to a value in a range of 1 nm to 5 nm, which will be described later.

Subsequently, as illustrated in FIG. 1C, an operation of forming a Mo metal film 13 on the tungsten metal underlying film 12 is performed.

The Mo metal film 13 may be formed by, for example, the sputtering method, the ALD method, or the CVD method. For example, the Mo metal film 13 is formed to be embedded in the recess formed in the SiO₂ film 11. A film thickness of the Mo metal film 13 is appropriately selected according to a device structure, such as a depth of the recess. Hereinafter, the tungsten metal underlying film 12 will be referred to as a “W film 12” and the Mo metal film 13 will be referred to as a “Mo film 13.”

As described above, in the case in which the Mo film 13 is formed on the wafer 10 having the SiO₂ film 11 formed thereon, when the W film 12 is formed as an underlying film of the Mo film 13, it is possible to reduce the specific resistance of the Mo film 13. Descriptions will be made below with reference to data about the specific resistance of the Mo film 13.

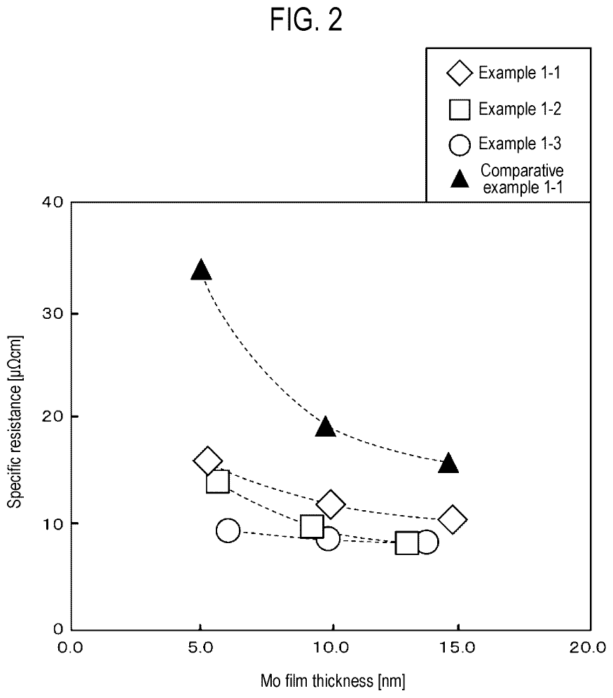

FIG. 2 is a characteristic graph illustrating the specific resistance of the Mo film 13 among the W film 12 and the Mo film 13 which are formed in an ex-situ condition. Results obtained by measuring the specific resistance while setting the film thickness of the W film 12 to 5 nm and changing the film thickness of the Mo film 13 in a range of 5 nm to 15 nm are shown. In FIG. 2, the horizontal axis represents the film thickness (nm) of the Mo film 13, and the vertical axis represents the specific resistance (μΩcm) of the Mo film 13. Further, the specific resistance of the Mo film 13 is calculated based on a resistance value of the W film 12 and a film thickness of the Mo film, which are estimated in advance from a result obtained by measuring a resistance value of a stacked film of the W film 12 and the Mo film 13. Unless otherwise specified, the specific resistance of the Mo film 13 is obtained similarly by the above-described method even in the following embodiments.

Here, the expression “the films are formed in the ex-situ condition” refers to a case in which the W film 12 is formed on the wafer 10 in a first processing module, the wafer 10 is exposed for a period of time to an ambient environment from a vacuum atmosphere, and subsequently, the Mo film 13 is formed on the W film 12 formed on the wafer 10 in a second processing module. In an experiment, the first processing module and the second processing module may be different modules or may be a same module. The formation of the W film 12 and the Mo film 13 in the ex-situ condition is performed to check the influence when the wafer 10 having the W film 12 formed thereon is exposed in the ambient environment.

In Example 1-1, the SiO₂ film 11 was formed in advance, the W film 12 was formed on the wafer 10 having a recess formed therein by the sputtering method, and then the Mo film 13 was formed by the sputtering method. Example 1-1 is plotted with a white rhombus (⋄) in FIG. 2.

The SiO₂ film is, for example, a thermal oxide film, and is formed by heating a silicon wafer in an oxygen atmosphere to oxidize a surface of the silicon wafer. An exemplary configuration of a sputtering device which performs the sputtering method is described in FIG. 18, which will be described later. In a film formation condition of the W film 12 formed using the sputtering device, a film formation temperature was room temperature and a pressure was 2.3×10⁻¹ Pa. In a film formation condition of the Mo film 13 formed using the sputtering device, a film formation temperature was room temperature and a pressure was 6.2×10⁻² Pa.

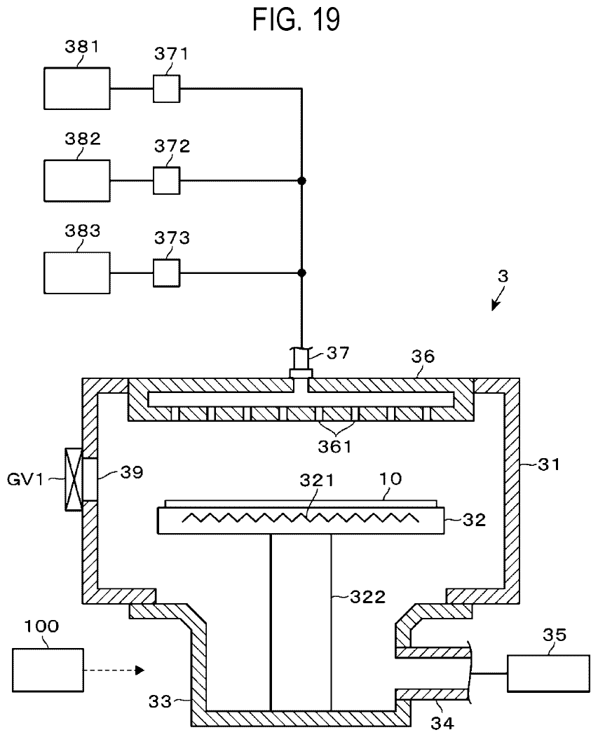

In Example 1-2 and Example 1-3, the SiO₂ film 11 was formed in advance, the W film 12 was formed on the wafer 10 having a recess formed therein by the sputtering method, and then the Mo film 13 was formed by the ALD method. In Example 1-2, a MoO₂Cl₂ gas (a first Mo-containing gas) was used as a raw material gas of the Mo film 13. Example 1-2 is plotted with a white square (□) in FIG. 2. Further, in Example 1-3, a gas containing oxygen-free molybdenum halide (a second Mo-containing gas) was used as the raw material gas of the Mo film 13. Example 1-2 is plotted with a white circle (∘) in FIG. 2. The SiO₂ film 11 and the W film 12 were formed similarly to those described in Example 1-1. An exemplary configuration of a film forming module which performs the ALD method will be described in FIG. 19. In a film formation condition of the Mo film 13 formed using the film forming module, a film formation temperature was 580 degrees C. and a pressure was 5.33 kPa for Example 1-2, and a film formation temperature was 530 degrees C. and a pressure was 1.33 kPa for Example 1-3.

In addition, in Comparative Example 1-1 illustrated in FIG. 2, the SiO₂ film 11 was formed in advance, the W film 12 was not formed on the wafer 10 having a recess formed therein, and the Mo film 13 alone was formed. Comparative Example 1-1 is plotted with a black triangle (▴). In Comparative Example 1-1, the Mo film 13 was formed by the sputtering method, and the SiO₂ film 11 and the Mo film 13 were formed similarly to those described in Example 1-1.

It was confirmed from FIG. 2 that in all of Example 1-1, Example 1-2, and Example 1-3, the specific resistance of the Mo film 13 is reduced as compared with Comparative Example 1-1. In particular, in a condition in which the thickness of the Mo film is 5 nm and the influence of the fine line effect is increased, it can be said that the specific resistance in each Example is remarkably reduced as compared with Comparative Example 1-1. Further, the fine line effect was confirmed even in Example 1-1, Example 1-2, and Example 1-3, but it was found that an increase in the specific resistance with respect to a decrease in the film thickness is relatively small. In particular, in Example 1-3, a variation in the specific resistance was extremely small. Further, it was found that the specific resistance when the film thickness of the Mo film 13 is about 10 nm, slightly exceeds 10 μΩcm in Example 1-1, but is 10 μΩcm or less in Example 1-2 and Example 1-3, which is considerably low as compared with Comparative Example 1-1.

In addition, it was found that in Example 1-3, the specific resistance of the Mo film 13 is further reduced as compared with Example 1-1 and Example 1-2. It is presumed that this is because the second Mo-containing gas used in Example 1-3 is a gas that contains no oxygen and contains halogen, and exhibits an action of etching a Mo oxide film while suppressing Mo from being oxidized. That is, in the ex-situ condition, since the wafer 10 having the W film 12 formed thereon is exposed to the ambient environment for a period of time, the surface of the W film 12 is oxidized. When the Mo film 13 is formed in Example 1-3, an oxide layer formed on the surface of the W film 12 is etched by the halogen contained in the second Mo-containing gas. Thus, the Mo film 13 is formed while the oxide layer is removed.

In particular, since the second Mo-containing gas contains no oxygen, oxidation of the W film 12 after the oxide layer is removed or oxidation of the formed Mo film 13 itself is suppressed. In contrast, in Example 1-1, it is presumed that since the Mo film 13 is formed on the oxide layer, the specific resistance of the Mo film 13 is increased as compared with that in Example 1-3 due to the presence of the oxide layer. Further, the first Mo-containing gas (the MoO₂Cl₂ gas) used in Example 1-2 contains halogen and has an ability to etch away the oxide layer on the surface of the W film 12. Meanwhile, since the first Mo-containing gas contains oxygen, for example, when oxygen is contained in the formed Mo film 13, it is considered that the specific resistance is increased as compared with that in Example 1-3.

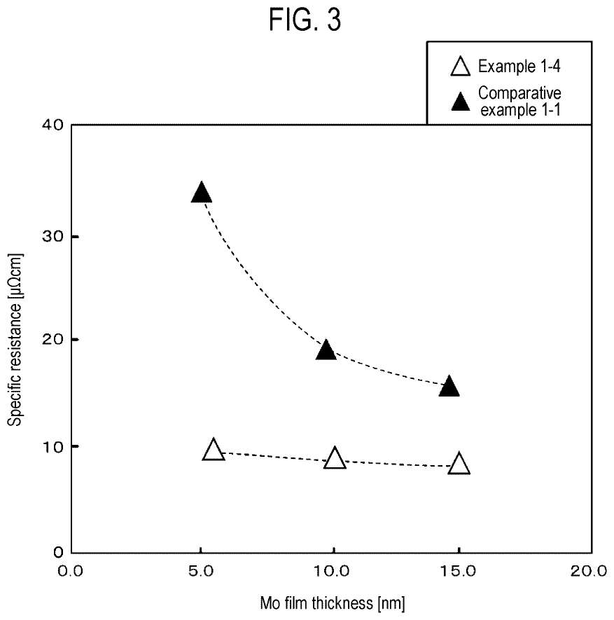

FIG. 3 is a characteristic graph illustrating the specific resistance of the Mo film 13 among the W film 12 and the Mo film 13, which are formed in an in-situ condition. Results obtained by measuring the specific resistance while setting the film thickness of the W film 12 to 5 nm and changing the film thickness of the Mo film 13 in a range of 5 nm to 15 nm are shown. In FIG. 3, the horizontal axis represents the film thickness (nm) of the Mo film 13, and the vertical axis represents the specific resistance (μΩcm) of the Mo film 13.

The expression “the films are formed in the in-situ condition” refers to a case in which the W film 12 is formed on the wafer 10 in the first processing module, the wafer 10 is transferred to the second processing module kept in the vacuum atmosphere, and the Mo film 13 is formed on the W film 12 formed on the wafer 10 in the second processing module. Further, the first processing module and the second processing module may be communalized into a single module, and the W film 12 and the Mo film 13 may be sequentially formed in the same module.

In FIG. 3, Example 1-4 is plotted with a white triangle (Δ), and Comparative Example 1-1 is plotted with a black triangle (▴). In Example 1-4, the SiO₂ film 11 was formed in advance, the W film 12 was formed on the wafer 10 having a recess formed therein by the sputtering method, and then the Mo film 13 was formed by the sputtering method. The formation of the SiO₂ film 11 and the formation of the W film 12 and the Mo film 13 by the sputtering method are similar to those illustrated in Example 1-1. Comparative Example 1-1 is the same as that described above.

As illustrated in FIG. 3, it was confirmed that in Example 1-4, the specific resistance of Mo film 13 is significantly reduced as compared with Comparative Example 1-1. In particular, it can be seen that when the film thickness of the Mo film 13 was about 5 nm, the specific resistance was about 8.8 μΩcm in Example 1-4, which is considerably low as compared with Comparative Example 1-1 in which the specific resistance is 27.5 μΩcm.

Further, it was found that in Example 1-4, a degree of the increase in the specific resistance with respect to the decrease in the film thickness is extremely small. Further, comparing Example 1-1, Example 1-2, Example 1-3, and Example 1-4, it was found that the specific resistance of the Mo film 13 in Example 1-3 and Example 1-4 exhibit approximately the same at a low level. It is presumed that this is because the W film 12 and the Mo film 13 are formed in the in-situ condition in Example 1-4, the formation of the oxide layer on the W film 12 is suppressed, and the increase in the specific resistance is suppressed. Therefore, it is considered that like Example 1-3 and Example 1-4, by employing the film forming method of suppressing the formation of the oxide layer between the W film 12 and the Mo film 13 (the selection of the oxygen-free Mo-containing gas or the film formation in the in-situ condition), it is possible to further reduce the specific resistance of the Mo film 13.

From the results illustrated in FIGS. 2 and 3, it is understood that when forming the Mo film 13 on the wafer 10 having the SiO₂ film 11 formed thereon, the W film 12 may be formed as the underlying film of the Mo film 13 to significantly reduce the specific resistance of the Mo film 13. In particular, in Example 1-3 and Example 1-4, although the Mo film 13 is a thin film having a film thickness of 5 nm, it has a specific resistance of 10 μΩcm or less, which is effective as a wiring material.

Reasons that the specific resistance of the Mo film 13 is reduced are understood as follows. As one reason, the Mo film 13 is formed on the underlying film as the W film 12 so that the grain size of the Mo film 13 may be increased two to three times. It is presumed that this is because the Mo film 13 grows due to the influence of W having a grain size larger than that of Mo. As described above, since a correlation exists between the grain size and the specific resistance, by forming the Mo film 13 having a relatively large grain size, it is possible to reduce the specific resistance of the Mo film 13.

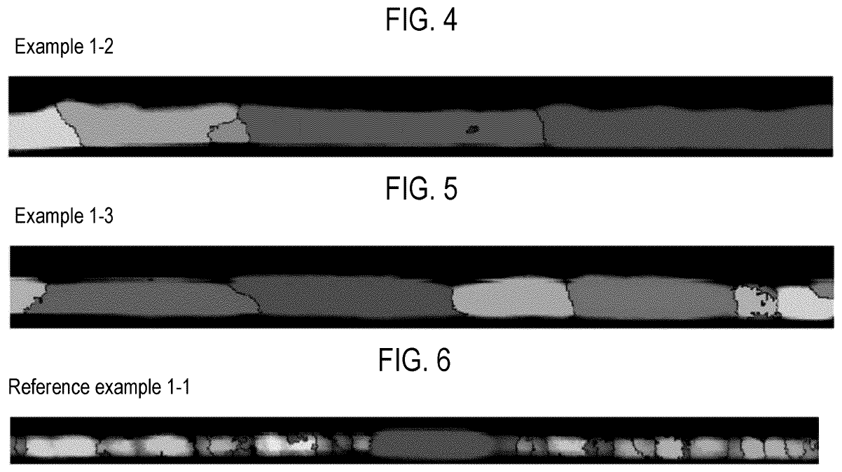

FIGS. 4, 5, and 6 show crystal grain maps obtained by analyzing with a transmission electron microscope (TEM), respectively. In the crystal grain maps, an azimuth orientation difference of 5 degrees or less is defined as a same grain, and the same grain is painted with a common color to distinguish from other grains (the original figures are illustrated in color). FIG. 4 illustrates the crystal grain map according to Example 1-2 (the thickness of the W film: 5 nm, and the thickness of the Mo film: 13 nm), FIG. 5 illustrates the crystal grain map according to Example 1-3 (the thickness of the W film: 5 nm, and the thickness of the Mo film: 14 nm), and FIG. 6 illustrates the crystal grain map according to Reference Example 1-1. In Reference Example 1-1, the W film having the thickness of 5 nm is formed on the wafer 10 having the SiO₂ film 11 formed thereon by the sputtering method.

In the crystal grain maps, an average grain size of metal crystals included in each film was 68.9 nm in Example 1-2, 54.4 nm in Example 1-3, and 25.5 nm in Reference Example 1-1. It was found that the average grain size in each of Example 1-2 and Example 1-3 is more than twice as large as that in Reference Example 1-1.

As described above, the grain size of the Mo film 13 is larger in the stacked film of the W film 12 and the Mo film 13 (see FIGS. 4 and 5) than the W film alone (see FIG. 6). Further, in FIGS. 4 and 5, a boundary that vertically partitions the W film 12 and the Mo film 13 was not confirmed, and the average grain size of the W film 12 and the Mo film 13 is larger than that of the W film alone. From this, it is presumed that by forming the Mo film 13 on the W film 12, the grains of the W film 12 grow integrally with those of the Mo film 13. However, as will be described later, an increase in the grain size of the W film 12 is considered to be minimally influenced by an annealing effect due to exposure to a high film formation temperature (for example, 580 degrees C.) in the formation of the Mo film 13.

In addition, in Example 1-3 (the thickness of the W film: 5 nm, and the thickness of the Mo film: 14 nm), it was found that as a result obtained by analyzing the grain size of the Mo film 13 using TEM, an average value of the grain size is 48 nm. The grain size was more than twice as large as the grain size of the Mo film 13 in which the W film 12 is not formed as the underlying film.

In addition, in Example 1-3, it was found that as a result obtained by TEM-based capturing, the SiO₂ film 11, the W film 12, and the Mo film 13 are formed in a stacked structure, and crystals of Mo and crystals of W have almost the same size (not illustrated). From this result, it is presumed that Mo and W are integrated with each other and grains of Mo grow on grains of W as a base. Further, by additionally analyzing elements included in each film using energy dispersive X-ray spectroscopy (EDX), the stacked structure constituted with the SiO₂ film 11, the W film 12, and the Mo film 13 was confirmed.

From these results, it is understood that when the W film 12 is formed as the underlying film of the Mo film 13, the grains of W influence the growth of Mo to promote an increase in the grain size of the Mo film 13. As a result, the specific resistance is reduced.

In addition, as another reason, a crystal structure of the W film 12 also seems to contribute to reduce the specific resistance of the Mo film 13.

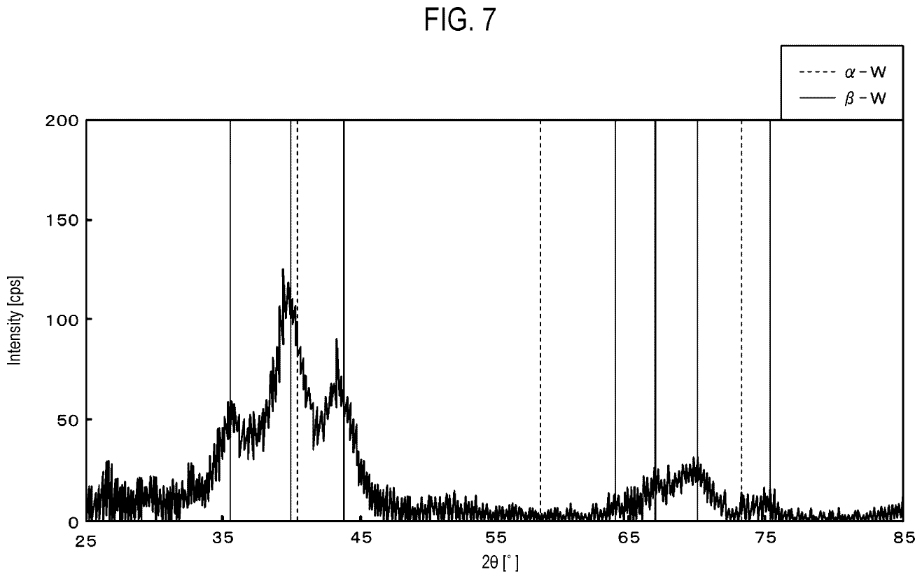

FIG. 7 shows a result obtained by analyzing, through X-ray diffraction (XRD), a crystal structure of the W film (having the film thickness of 5 nm) formed on the wafer 10 having the SiO₂ film 11 formed thereon by the sputtering method. In FIG. 7, the horizontal axis represents a diffraction angle 20, and the vertical axis represents an intensity (CPS: counts per second). As the crystal structure of the W film, there are known a stable body-centered cubic structure (α phase) and a metastable A15 type structure (β phase). A diffraction angle of the α phase is indicated by a broken line, and a diffraction angle of the β phase is indicated by a solid line.

As illustrated in FIG. 7, it was found that the W film formed on the SiO₂ film 11 by the sputtering method has a peak corresponding to the diffraction angle of the α phase but has many peaks corresponding to the diffraction angle of the β phase. Thus, the W film includes many crystals of the β phase.

As described above, when the Mo film 13 is formed on the W film 12 as the underlying film, the grain size of the Mo film 13 is increased. In this case, it is presumed that the W film 12 grows while being oriented to the β phase, which also influences in increasing in the grain size. For example, it is presumed that when the Mo film 13 is formed on the W film 12 having a crystal structure in which a content ratio of the β phase is high, the grain size of the Mo film 13 is increased and the specific resistance is reduced.

In a second embodiment to be described later, it was confirmed that in a configuration in which the W film 12 is stacked on a titanium nitride film (TiN film), a crystal phase included in the W film 12 is mainly the α phase. Therefore, it is presumed that by stacking the W film 12 on the SiO₂ film 11, it is possible to form the W film 12 having a high content ratio of the β phase. In this example, a SiO₂ film formed by a thermal oxide film is used, but the method of forming the SiO₂ film 11 or the W film 12 has little influence on a content of the β phase in the W film 12. For example, it is considered that by forming a W film on a film (the SiO₂ film 11) including silicon (Si) and O by the above-described sputtering method, it is possible to increase the content of the β phase in the W film 12. In this case, the method of forming the SiO₂ film 11 may performed by the CVD method or the ALD method, which uses a SiH₄ gas and an O₂ gas as raw materials. Further, the method may be a spin coating method of forming the SiO₂ film 11 by supplying a polysilazane solution to the wafer 10 which is rotating, and then heating the wafer 10.

As described above, it was confirmed that in FIGS. 4 to 7, the Mo film 13 with a large grain size is obtained by the ALD method using two kinds of raw materials. According to these experimental results, there is a correlation between the grain size and the specific resistance of the Mo film 13. The present disclosure is not limited to the Mo film 13 formed by the ALD method. It is considered that even in the Mo film 13 formed by the sputtering method, the formation of the W film 12 provides an effect of increasing the grain size of the Mo film 13. In general, it is known that the grain size is increased by anneal processing. However, the film formation of the Mo film is performed at room temperature by the sputtering method. Therefore, when forming the Mo film 13 on the W film 12 as the underlying film, it is considered that the effect of heat during film formation on increasing the grain size of the Mo film 13 is small.

Accordingly, the anneal processing was performed on the stacked film of the W film 12 and the Mo film 13 in Example 1-3 at 850 degrees C. for two minutes to check the influence of the anneal processing. As a result, a significant change in the grain size was not recognized before/after the anneal processing. In contrast, it is presumed that, according to the method of the present disclosure, since the grain size of the Mo film 13 has already been increased in the film formation of the Mo film 13, the influence of the anneal processing on the growth of the grain size is small.

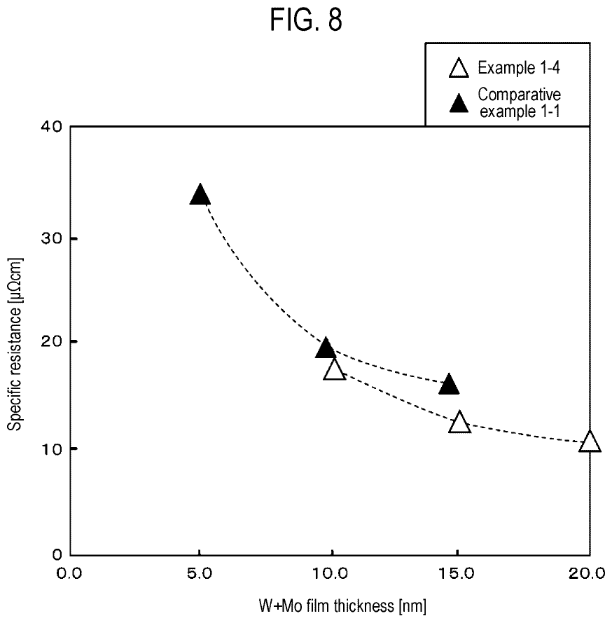

As described above, the Mo film 13 having low specific resistance may be formed by the method of the present disclosure. However, in practice, when the stacked film of the W film 12 and the Mo film 13 is used for a semiconductor device, the specific resistance of the entire stacked structure becomes problematic. In this regard, the specific resistance was measured with respect to the stacked film of Example 1-4. Results are shown in FIG. 8. In FIG. 8, the horizontal axis represents the total film thickness (nm) of the W film 12 and the Mo film 13 (the stacked film), and the vertical axis represents the specific resistance (μΩcm) of the stacked film. Further, in the stacked film of Example 1-4, the film thickness of the W film 12 was set to 5 nm and the film thickness of the Mo film 13 was changed to 5 nm, 10 nm, and 15 nm. Further, in FIG. 8, Example 1-4 is plotted with a white triangle (Δ), and Comparative Example 1-1 is plotted with a black triangle (▴).

In FIG. 8, comparing Comparative Example 1-1 and Example 1-4, it was found that when the film thickness of the Mo film (Comparative Example 1-1) and the film thickness of the stacked film of the W film 12 and the Mo film 13 are the same, the specific resistance is small in the stacked film rather than the Mo film alone.

The specific resistance of the stacked film was about 17.3 μΩcm when the total film thickness is 10 nm, about 12.6 μΩcm when the total film thickness is 15 nm, and about 10 μΩcm when the total film thickness is 20 nm. The present inventors aimed to set the specific resistance of the stacked film having the total film thickness of, for example, 10 nm, to 20 μΩcm or less. In this regard, it is considered that the stacked film of the W film 12 and the Mo film 13, which is obtained by the method of the present disclosure, may be sufficiently used as a wiring material of the semiconductor device.

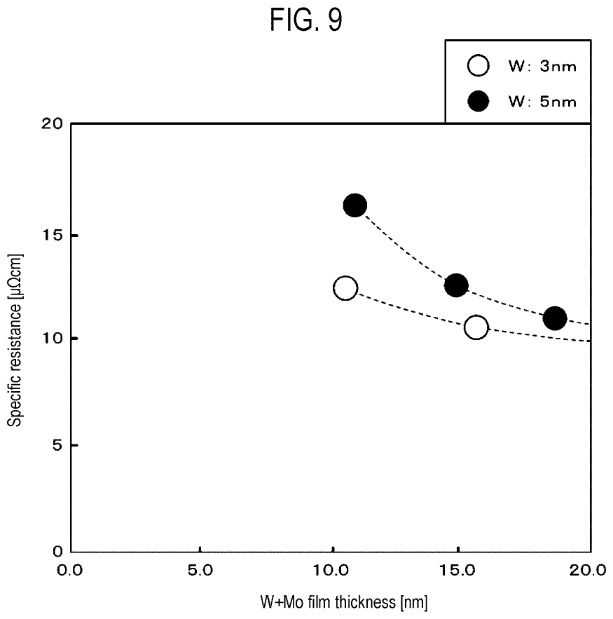

FIG. 9 shows an influence of a change in the film thickness of the W film 12 on the specific resistance of the stacked film. FIG. 9 illustrates a result obtained by measuring the specific resistance of the stacked film in a case in which the film thickness of the W film 12 in the stacked film of Example 1-3 is set to 5 nm and 3 nm. In FIG. 9, the horizontal axis represents the total film thickness (nm) of the W film and the Mo film (the stacked film), and the vertical axis represents the specific resistance (μΩcm) of the stacked film. The case in which the film thickness of the W film is 3 nm is plotted with a white circle (∘), and the case in which the film thickness of the W film is 5 nm is plotted with a black circle (●).

As illustrated in FIG. 9, it was found that when the film thickness of the W film 12 is set from 5 nm to 3 nm, the specific resistance of the stacked film is further reduced. That is, it was confirmed that when the total film thickness of the W film 12 and the Mo film 13 is about the same, by making the film thickness of the W film 12 thinner and the film thickness of the Mo film 13 thicker, it is possible to reduce the specific resistance of the stacked film. The specific resistance of W is higher than that of Mo. Thus, when the film thickness of W is thin, the specific resistance thereof is further increased by the fine line effect. Thus, it is understood that, by thickening the film thickness of Mo by an amount corresponding to the thinned film thickness of W, the specific resistance of the entire stacked film is reduced. However, when the film thickness of the W film 12 is made excessively thin, the growth of the grains of the Mo film 13 may be deteriorated, which may cause an increase in the specific resistance of the Mo film 13. In view of this point, the film thickness of the W film 12 may be set in a suitable range. For example, the film thickness of the W film 12 may be set to 1 nm to 5 nm, specifically a value in a range of 2 nm to 3 nm.

Next, the influence of the film formation temperature of the Mo film 13 was checked. As described above, the Mo film 13 may be formed by the sputtering method, the ALD method, the CVD method, or the like. In general, the sputtering method is carried out at room temperature, but the ALD method or the CVD method may often be carried out at a high temperature, for example, a temperature of 350 degrees C. or higher. A wiring forming process is preferably performed at a temperature of 400 degrees C. or lower. In this regard, a relationship between the film formation temperature and the specific resistance when the Mo film 13 is formed by the ALD method was examined.

Specifically, in a process illustrated in Example 1-3, the Mo film 13 was formed on the W film 12 having film thicknesses of 3 nm and 5 nm, a stacked film of the Mo film 13 and the W film 12 was formed while changing the film formation temperature of the Mo film 13 and the film thickness of the Mo film 13 with respect to each of the film thicknesses of 3 nm and 5 nm, and the specific resistance of the stacked film was measured.

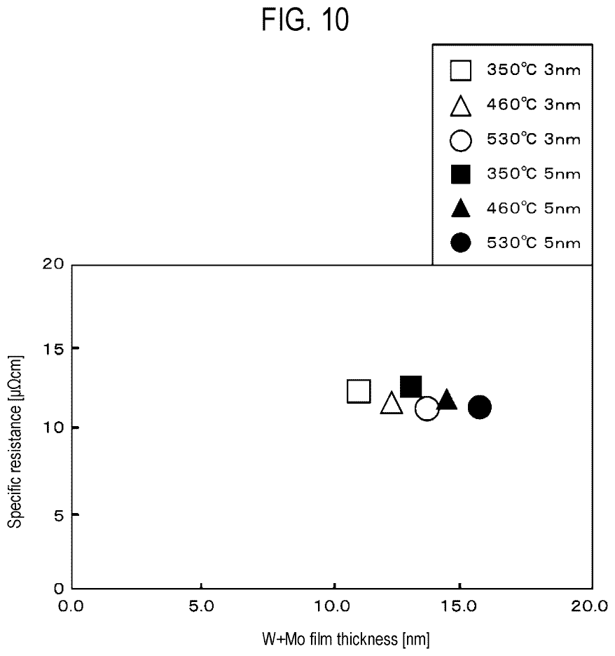

The results are shown in FIG. 10. In FIG. 10, the horizontal axis represents the total film thickness (nm) of the W film 12 and the Mo film 13 (the stacked film), and the vertical axis represents the specific resistance (μΩcm) of the stacked film. In FIG. 10, when the film thickness of the W film 12 is 3 nm, a case in which the film formation temperature of the Mo film 13 is 350 degrees C. is plotted with a white square (□), a case in which the film formation temperature of the Mo film 13 is 460 degrees C. is plotted with a white triangle (Δ), and a case in which the film formation temperature of the Mo film 13 is 530 degrees C. is plotted with a white circle (∘). Further, when the film thickness of the W film 12 is 5 nm, a case in which the film formation temperature of the Mo film 13 is 350 degrees C. is plotted with a black square (▪), a case in which the film formation temperature of the Mo film 13 is 460 degrees C. is plotted with a black triangle (▴), and a case in which the film formation temperature of the Mo film 13 is 530 degrees C. is plotted with a black circle (●).

From FIG. 10, it was found that when the film thickness of the W film 12 is set to 3 nm and 5 nm, the specific resistance of the stacked film tends to become slightly smaller as the film formation temperature of the Mo film 13 increases, but there is no significant change. Therefore, it was confirmed that even if the stacked film of the W film 12 and the Mo film 13 is formed at a temperature of 400 degrees C. or lower, the stacked film having a relatively low specific resistance is formed. As described above, the method of the present disclosure may be applied to a low-temperature wiring forming process in which a process is performed at 400 degrees C. or lower and thus is effective.

According to this embodiment, the W film 12 is used as the metal underlying film of the Mo film 13, and the Mo film 13 is formed on the W film 12 so that the grain size of the Mo film 13 may be increased and the Mo film 13 having a relatively low specific resistance may be formed. Further, by stacking the W film 12 on the SiO₂ film 11 formed on the wafer 10, it is possible to form the W film having a large content of the β phase as a crystal phase. This makes it possible to further reduce the specific resistance of the Mo film. As a result, in a miniaturized semiconductor device, the Mo film 13 formed by the method of the present disclosure may be used as a wiring material, which suppresses the specific resistance from being increased due to the fine line effect. This resolves issues such as heat generation of wiring or wiring delay, which may be causes of increasing the specific resistance.

### Second Embodiment

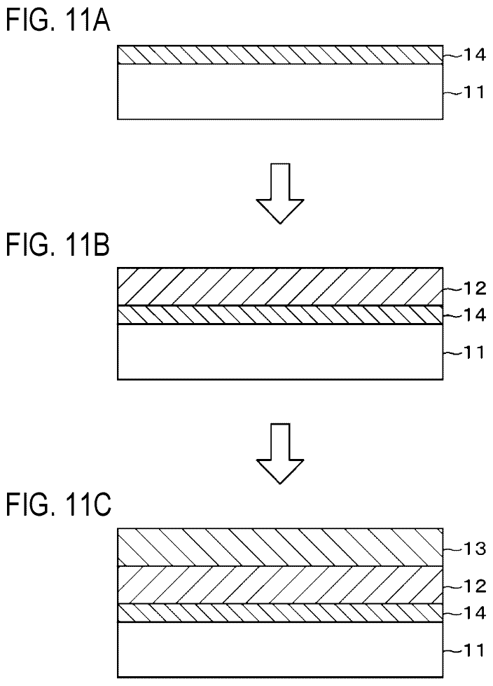

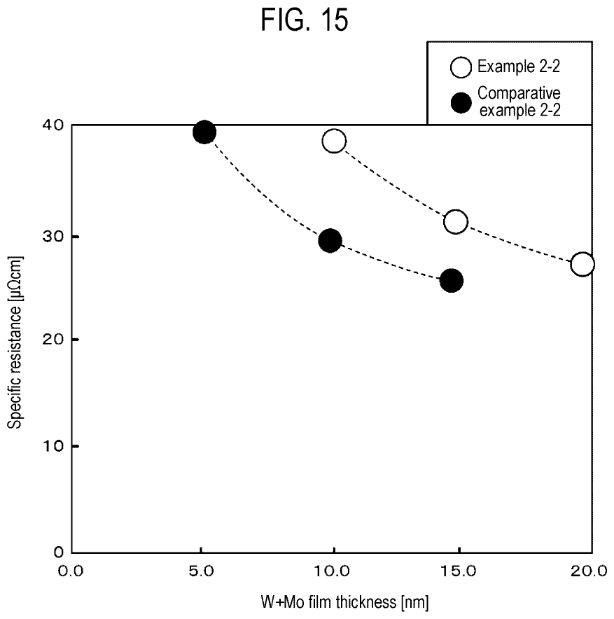

Next, a second embodiment of the present disclosure will be described with reference to FIGS. 11A to 11C and FIG. 15. In the second embodiment, a titanium nitride film (TiN film) 14 is formed on the SiO₂ film 11, which is formed on the wafer 10 and has a recess (FIG. 11A). Subsequently, the W film 12 is formed on the TiN film 14 (FIG. 11B). Thereafter, as illustrated in FIG. 11C, the Mo film 13 is formed on the W film 12. Thus, in this embodiment, the W film 12 is stacked on the TiN film 14.

The TiN film 14 has, for example, a function of an adhesion layer, and a film thickness thereof is set in, for example, a range of 2 nm to 3 nm. The TiN film 14 is formed with a gas containing titanium (Ti), for example, a titanium tetrachloride (TiCl₄) gas, and a gas containing nitrogen (N), for example, an ammonia (NH₃) gas, by the ALD method or the CVD method.

Further, in this example, like the first embodiment, the W film 12 or the Mo film 13 may be formed by the sputtering method, the ALD method, or the CVD method.

As described above, even if the TiN film 14 is formed on the wafer 10 and the stacked film of the W film 12 and the Mo film 13 is formed on the TiN film 14, the specific resistance of the Mo film 13 may be reduced as compared with a case where only the Mo film 13 is formed on the wafer 10. Hereinafter, descriptions will be made with reference to data about the specific resistance of the Mo film 13.

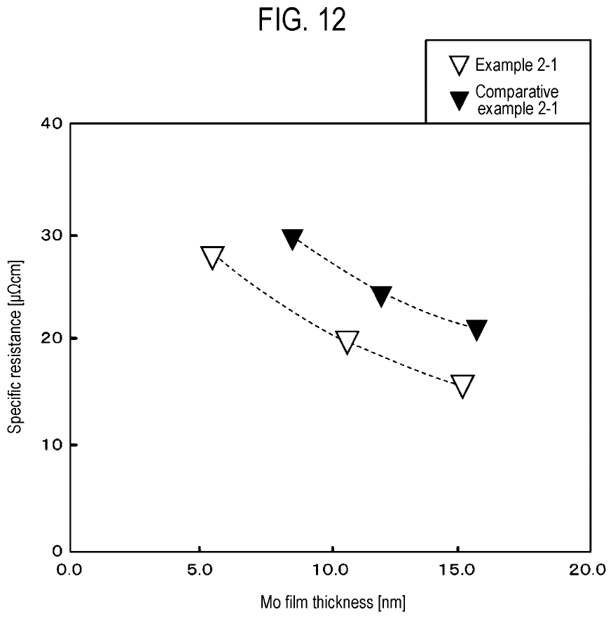

FIG. 12 is a characteristic graph illustrating the specific resistance of the Mo film 13 among the W film 12 and the Mo film 13, which are formed in the ex-situ condition. Results obtained by measuring the specific resistance while setting the thickness of the TiN film 14 to 3 nm, the film thickness of the W film 12 to 5 nm, and changing the film thickness of the Mo film 13 in a range of 5 nm to 15 nm are shown. In FIG. 12, the horizontal axis represents the film thickness (nm) of the Mo film 13, and the vertical axis represents the specific resistance (μΩcm) of the Mo film 13. In FIG. 12, Example 2-1 is plotted with a white inverted triangle (∇), and Comparative Example 2-1 is plotted with a black inverted triangle (▾).

In Example 2-1, the SiO₂ film 11 was formed in advance, the TiN film 14 was formed on the wafer 10 having a recess formed therein by the ALD method, the W film 12 was formed by the sputtering method, and subsequently, the Mo film 13 was formed using the second Mo-containing gas as a raw material gas by the ALD method.

The SiO₂ film 11, the W film 12, and the Mo film 13 were formed similarly to those illustrated in Example 1-3. Further, in a film formation condition of the TiN film 14, the TiCl₄ gas was used as a raw material gas, a NH₃ gas was used as a nitride gas, a film formation temperature was 460 degrees C., and a pressure was 667 Pa.

In Comparative Example 2-1, the TiN film 14 was formed on the wafer 10 having the SiO₂ film formed thereon, and then the Mo film 13 was formed on the TiN film 14 using the second Mo-containing gas by the ALD method. A film thickness of the TiN film 14 was 3 nm, and film formation conditions of the SiO₂ film 11, the TiN film 14, and the Mo film 13 were similar to those illustrated in Example 2-1.

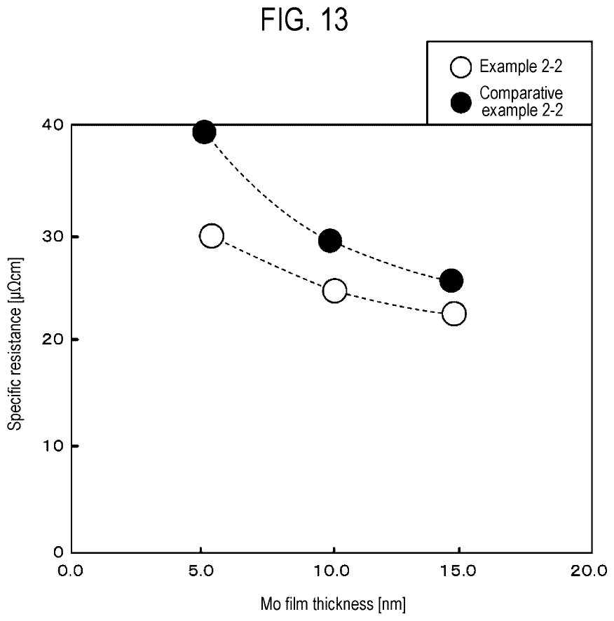

In addition, FIG. 13 is a characteristic graph illustrating the specific resistance of the Mo film 13 among the W film 12 and the Mo film 13, which are formed in the in-situ condition. Results obtained by measuring the specific resistance while setting the film thickness of the TIN film 14 to 3 nm, the film thickness of the W film 12 to 5 nm, and changing the film thickness of the Mo film 13 in a range of 5 nm to 15 nm are shown. In FIG. 13, the horizontal axis represents the film thickness (nm) of the Mo film 13, and the vertical axis represents the specific resistance (μΩcm) of the Mo film 13. In FIG. 13, Example 2-2 is plotted with a white circle (∘), and Comparative Example 2-2 is plotted with a black circle (●).

In Example 2-2, the TiN film 14 was formed on the wafer 10 having the SiO₂ film 11 formed thereon, the W film 12 was formed on the TiN film 14 by the sputtering method, and the Mo film 13 was formed on the W film 12 by the sputtering method. The SiO₂ film 11, the W film 12, and the Mo film 13 were formed similarly to those illustrated in Example 1-4, and the TiN film 14 was formed similarly to that illustrated in Example 2-1.

In Comparative Example 2-2, the TiN film 14 was formed on the wafer 10 having the SiO₂ film 11 formed thereon, and then the Mo film 13 was formed on the TiN film 14 by the sputtering method. The film thickness of the TiN film 14 was 3 nm, and the SiO₂ film 11, the TiN film 14, and the Mo film 13 were formed similarly to those illustrated in Example 2-2.

From FIG. 12, it was confirmed that as compared with Comparative Example 2-1, in Example 2-1, the specific resistance of the Mo film 13 is reduced when the film thickness of the Mo film 13 is about the same. Further, from FIG. 13, it was confirmed that as compared with Comparative Example 2-2, in Example 2-2, the specific resistance of the Mo film 13 is reduced when the film thickness of the Mo film 13 is about the same.

From data illustrated in FIGS. 12 and 13, it was found that even if the TiN film 14 is formed on the wafer 10, and the Mo film 13 is formed on the TiN film 14, the W film 12 is formed as the underlying film of the Mo film to reduce the specific resistance of the Mo film 13. However, like the first embodiment, it was found that, by stacking the W film 12 on the SiO₂ film 11, it is possible to further reduce the specific resistance of the Mo film 13.

The reason for this has been described that in the first embodiment, the crystal structure of W underlying below the Mo film 13 has a large content of the β phase. However, in the second embodiment, it is presumably because the crystal structure of the W film underlying below the Mo film 13 mainly includes the α phase.

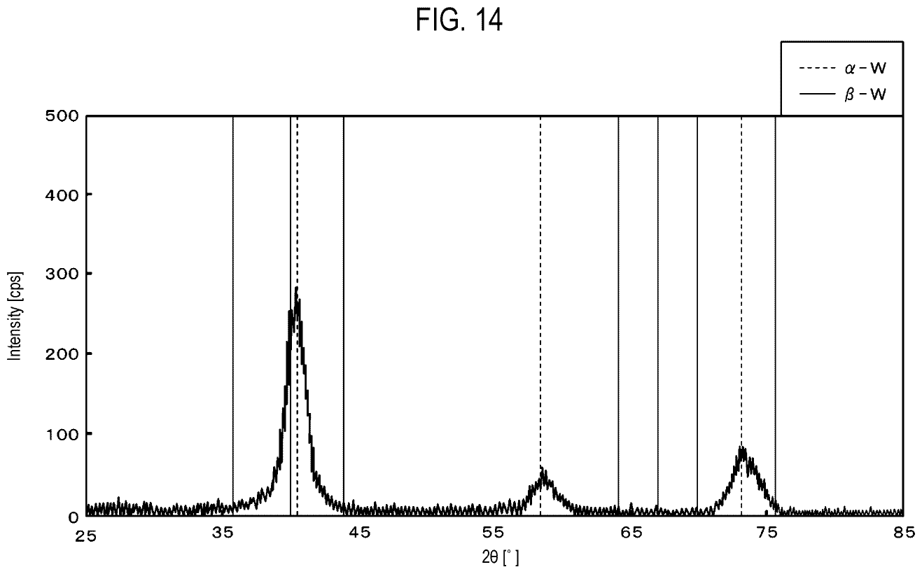

FIG. 14 shows results obtained by analyzing, with XRD, the crystal structure of the W film 12 (having the film thickness of 5 nm) formed on the wafer 10 having the TiN film 14 (having the film thickness of 3 nm) formed thereon by the sputtering method. In FIG. 14, the horizontal axis represents the diffraction angle 20 (degree), and the vertical axis represents the intensity (CPS). The diffraction angle of the α phase is indicated by a broken line, and the diffraction angle of the β phase is indicated by a solid line.

As illustrated in FIG. 14, it was found that the W film 13 formed on the TiN film 14 has many peaks corresponding to the diffraction angle of the α phase while peaks corresponding to the diffraction angle of the β phase are hardly observable, and therefore the crystal phase of the W film 13 is mainly the α phase.

From the results illustrated in FIGS. 7 and 14, it was confirmed that, when the W film 12 is formed on the SiO₂ film 11, the crystal phase of the W film 12 has a large content of the β phase, and when the W film 12 is formed on the TiN film 14, the crystal phase of the W film 12 is mainly the α phase.

As described above, the W film 12 of this embodiment mainly has the α phase. When the W film 12 is used as the underlying film, the specific resistance of the Mo film 13 is reduced as compared with that in Comparative Example. Further, comparing Example 2-2 of FIG. 13 and Comparative Example 1-1 (example in which the Mo film 13 is formed on the SiO₂ film 11) of FIG. 3, it was found that when the film thickness of the Mo film 13 is 5 nm, the specific resistance of the Mo film 13 is low in Example 2-2. From this, it is presumed that although the stack of the W film 12 on the TiN film 14 has a smaller effect than in the case of the stack of the W film 12 on the SiO₂ film 11, it increases the grain size of the Mo film 13 and thus reduces the specific resistance.

Even in this embodiment, a measurement was made for the specific resistance of the stacked film of the W film 12 and the Mo film 13, which is stacked on the TiN film 14. Measurement results are illustrated in FIG. 15. In FIG. 15, the horizontal axis represents the total film thickness (nm) of the W film and the Mo film (the stacked film), and the vertical axis represents the specific resistance (μΩcm) of the stacked film. Example 2-2 is plotted with a white circle (∘), and Comparative Example 2-2 is plotted with a black circle (●). As described above, in Example 2-2, the W film 12 and the Mo film 13 were formed in the in-situ condition.

As described above, comparing Example 2-2 and Comparative Example 2-2, it was found that, when the film thickness of the Mo film 13 is 5 nm (the film thickness of the stacked film in Example 2-2 is 10 nm), the specific resistance of the stacked film of the W film 12 and the Mo film 13 is lower than that of the Mo film 13. Therefore, it is understood that, for example, even in the case in which the TiN film 14 is formed as an adhesion layer on the wafer 10, the stacked film may be sufficiently used as the wiring material of the semiconductor device.

As described above, even in the second embodiment, the W film 12 is formed as the metal underlying film of the Mo film 13, and the Mo film 13 is formed on the W film 12. This makes it possible to increase the grain size of the Mo film 13 and to form the Mo film 13 having a relatively low specific resistance.

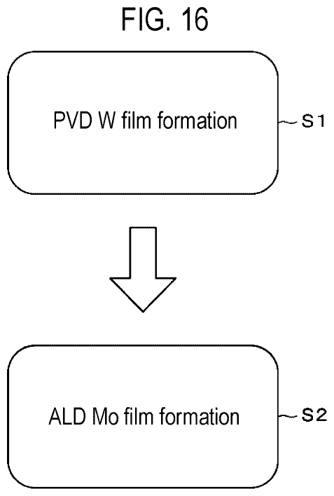

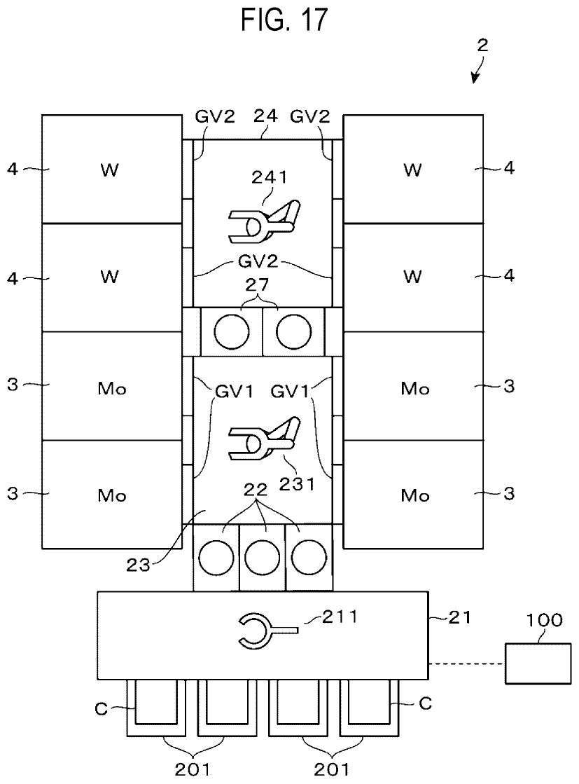

Next, an apparatus for forming a Mo metal film on the wafer 10 (hereinafter, referred to a “film forming apparatus”) will be described with reference to FIGS. 16 and 17 by taking, as an example, the apparatus for forming the W film 12 and the Mo film according to the first embodiment. As illustrated in FIG. 16, a film forming apparatus 2 performs Operation S1 of forming the W film 12 on the wafer 10 having the SiO₂ film 11 formed thereon by the sputtering method (PVD: physical vapor deposition), and Operation S2 of forming the Mo film 13 on the W film 12 by the ALD method.

As illustrated in FIG. 17, the film forming apparatus 2 is configured to include an atmospheric transfer chamber 21, a load lock chamber 22, a first vacuum transfer chamber 23, and a second vacuum transfer chamber 24. The atmospheric transfer chamber 21 is set to be in an atmospheric pressure atmosphere, and is configured to transfer a plurality of wafers 10 between a carrier C that accommodates the wafers 10 and the load lock chamber 22 by an atmospheric transfer mechanism 211 disposed inside the atmospheric transfer chamber 21. The carrier C is placed on a load port 201. The SiO₂ film 11 is formed in advance on the wafer 10 accommodated in the carrier C, and has the recess formed therein.

The load lock chamber 22 transfers the wafers 10 between the atmospheric transfer mechanism 211 and a first substrate transfer mechanism 281 disposed inside the first vacuum transfer chamber 23. The load lock chamber 22 is configured such that an interior thereof is capable of being regulated to have an atmospheric pressure and an internal pressure of the first vacuum transfer chamber 23.

The first vacuum transfer chamber 23 and the second vacuum transfer chamber 24 have a quadrangular shape in a plan view, and are connected to each other via, for example, two deliverers 27. Interiors of the first vacuum transfer chamber 23, the second vacuum transfer chamber 24, and the deliverers 27 are set to be in a vacuum pressure atmosphere. For example, the first vacuum transfer chamber 23 is configured to have a vacuum degree lower than that of the second vacuum transfer chamber 24. Each deliverer 27 transfers the wafers 10 to and from a first substrate transfer mechanism 231 provided in the first vacuum transfer chamber 23 or to and from a second substrate transfer mechanism 241 provided in the second vacuum transfer chamber 24. Therefore, each deliverer 27 is configured such that the internal pressure thereof is capable of being regulated to an internal pressure of the first vacuum transfer chamber 23 and an internal pressure of the second vacuum transfer chamber 24.

For example, two Mo film forming modules 3 are connected to each of wall portions of the first vacuum transfer chamber 23 in a lateral direction. In this example, the Mo film forming module 3 constitutes the second processing module, and is configured to form the Mo film 13 by the ALD method. Further, the first vacuum transfer mechanism 231 is configured to transfer the wafers 10 among the four Mo film forming modules 3, the deliverers 27, and the load lock chambers 22.

In addition, for example, two W film forming modules 4 are connected to each of wall portions of the second vacuum transfer chamber 24 in the lateral direction. In this example, the W film forming module 4 constitutes the first processing module, and is configured to form the W film 12 by the sputtering method. Further, the second vacuum transfer mechanism 241 is configured to transfer the wafers 10 among the four W film forming modules 4 and the deliverers 27. In FIG. 17, reference numerals GV1 and GV2 indicate gate valves.

In addition, transfer ports for the wafers and gate valves which open/close the transfer ports are provided between the first and second vacuum transfer chambers 23 and 24 and the deliverers 27, between the load lock chambers 22 and the first vacuum transfer chamber 23, and between the load lock chambers 22 and the atmospheric transfer chamber 21, respectively. Details thereof are omitted herein.

The film forming apparatus 2 configured as above includes a controller 100. The controller 100 is constituted with a computer including a storage which stores programs, a memory, and a CPU. The programs are configured to output control signals for performing control required to perform processing on the wafer 10 from the controller 100 to individual constituent elements of the film forming apparatus 2.

The programs are stored in the storage of the computer, for example, a flexible disk, a compact disk, a hard disk, a magneto-optical disk (MO), a non-volatile memory, or the like, and are read from the storage and installed in the controller 100. An operation of transferring the wafers 10 in the film forming apparatus 2, an operation of forming the W film 12 in the W film forming module 4, and an operation of forming the Mo film 13 in the Mo film forming module 3 are performed based on the control signals from the controller 100.

Next, an exemplary configuration of the W film forming module 4 constituting the first processing module will be described with reference to FIG. 18. The W film forming module 4 is configured as a sputtering device for forming the W film 12 on the wafer 10 by the sputtering method.

As illustrated in FIG. 18, the W film forming module 4 includes a processing container 41, a stage 42 provided inside the processing container 41 to place the wafer 10 thereon, and a target 43 which releases a metal (W) toward the wafer 10 placed on the stage 42.

For example, the processing container 41 is configured to include a main body 411 which is a substantially cylindrical container having an open upper surface, and a cover body 412 which closes an opening of the main body 411. A gate valve GV connected to the second vacuum transfer chamber 24 is provided in a sidewall surface of the main body 411. Further, a vacuum exhauster (not illustrated) which evacuates an interior of the processing container 41 is connected to the main body 411.

In this example, the cover body 412 includes a horizontal ceiling portion 413 smaller in size than the main body 411 in a plan view, and an inclined portion 414 which connects the ceiling portion 413 and an upper end of the sidewall surface of the main body 411. A gas supply 49 for supplying a raw material gas (for example, an argon gas (Ar gas)) of ions for sputtering into an inner space of the processing container 41 is connected to a central portion of the ceiling portion 413.

In addition, the inclined portion 414 of the cover body 412 is provided with a holder 40 which holds the target 43, and a holder support 44 made of an insulator for fixing the holder 40 to the cover body 412. The holder 40 is connected to a power source 45.

The stage 42 includes a stage main body 421 and an electrostatic chuck 422 for fixing the wafer 10 to the stage 42. The stage 42 is connected to a driver 424 provided below the processing container 41 by a drive shaft 423 provided at a central portion of a lower surface thereof. With this configuration, the stage 42 is provided to be rotatable around a vertical axis and is configured to move up and down between a delivery position and a processing position shown in FIG. 18. The delivery position is a position at which the wafer 10 is delivered between the second substrate transfer mechanism 241 of the second vacuum transfer chamber 24 and the stage 42, and the processing position is a position at which the film forming processing on the wafer 10 is performed and is defined above the delivery position.

A shield plate 46 for preventing W as the metal released from the target 43 from being deposited on a surface of the stage main body 421, and a mask 47 for forming a non-film forming region (region in which no metal film is formed) at a peripheral edge of the wafer 10 are disposed on an upper surface of the stage 42. The mask 47 is a circular ring-shaped member which corresponds to a region in which a W film as a metal film is formed and has a circular opening 471 having a diameter smaller than that of the wafer 10. In FIG. 18, reference numeral 48 designates a mask support. The mask support is configured to, when the wafer 10 is delivered between the stage 42 and the second substrate transfer mechanism 241, separate the mask 47 from the stage 42 and support the separated mask 47.

In the W film forming module configured as above, when the wafer 10 is at the processing position while being placed on the stage 42 and power is supplied from the power source 45 to the holder 40, an electric field is generated in the vicinity of the target 43 held by the holder 40. By the electric field, a gas supplied from the gas supply 49 is dissociated to generate ions. The ions collide with the target 43, so that W atoms and the like, which are raw materials of the W film, are released from the target 43. Further, W released from the target 43 is deposited on the wafer 10 via the opening 471 of the mask 47, so that the W film is formed on the surface of the wafer 10.

Next, an exemplary configuration of the Mo film forming module 3 constituting the second processing module will be described with reference to FIG. 19. The Mo film forming module 3 is configured as an apparatus, which forms the Mo film 13 on the wafer 10 by the ALD method.

As illustrated in FIG. 19, the Mo film forming module 3 includes a substantially cylindrical processing container 31 which accommodates and processes the wafer 10, and a stage 32 having the wafer 10 placed thereon is disposed inside the processing container 31. The stage 32 has, for example, a flat cylindrical shape, and includes a heater 321 incorporated therein. A support 322 which extends downward is provided at a center of a lower surface of the stage 32.

In this example, a central portion of a bottom wall of the processing container 31 protrudes downward to constitute an exhaust chamber 33. A lower end of the support 322 is connected to a bottom portion of the exhaust chamber 33. An exhaust mechanism 35 is connected to a sidewall of the exhaust chamber 33 via an exhaust path 34. Further, a transfer port 39 through which the wafer 10 is loaded to and unloaded from the processing container 31 is formed in a sidewall of the processing chamber 31. The transfer port 39 is configured to be opened/closed by the gate valve GV1.

A shower head 36 is disposed in a region facing the stage 32 inside the processing container 31. The shower head 36 is configured to discharge a gas in the form of a shower toward the wafer 10 placed on the stage 32 from a plurality of discharge ports 361 formed in a lower surface of the shower head 36.

In addition, a supply pipe 37 for supplying the gas to the shower head 36 is connected to the processing container 31. A base end of the supply pipe 37 is branched into plural lines to be connected to a source 381 of a raw material containing a metal, a source 382 of a reducing gas, and a source 383 of a purge gas. The branched lines of the supply pipes 37 include flow rate adjusters 371, 372, and 373 which are provided with valves configured to open/close flow paths thereof, mass flow meters, or the like, respectively. In this example, the first Mo-containing gas or the second Mo-containing gas is used as the raw material gas, a hydrogen (H₂) gas is used as the reducing gas, and an inert gas such as a nitrogen (N₂) gas or an Ar gas is used as the purge gas.

In the Mo film forming module 3 configured as above, the wafer 10 having the W film 12 formed thereon is placed on the stage 32, an internal pressure of processing container 31 is adjusted to a preset pressure by exhausting the interior of the processing chamber 31, and the wafer 10 on the stage 32 is heated to a preset temperature by the heater 321.

In addition, a cycle including sequentially supplying the raw material gas and the reducing gas in an order of the raw material gas→the purge gas→the reducing gas→the purge gas to the wafer 10 is carried out inside the processing container 31. The cycle is repeated a preset number of times until the Mo film 13 is formed at a set thickness.

In the film forming apparatus 2 shown in FIG. 17, the wafer 10 accommodated in the carrier C is transferred along a route of the atmospheric transfer chamber 21→the load lock chamber 22→the first vacuum transfer chamber 23→the deliverer 27→the second vacuum transfer chamber 24→the W film forming module 4. Then, in the W film forming module 4, the W film 12 is formed on the wafer 10 by the sputtering method. Subsequently, the wafer 10 is transferred along a route of the second vacuum transfer chamber 24→the deliverer 27→the first vacuum transfer chamber 23→the Mo film forming module 3. In the Mo film forming module 3, the Mo film 13 is formed on the W film 12 formed on the wafer 10 by the ALD method. Thereafter, the wafer 10 is accommodated in the original carrier C along a route of the first vacuum transfer chamber 23→the load lock chamber 22→the atmospheric transfer chamber 21→the carrier C.

In this example, since the wafer 10 is transferred from the W film forming module 4 to the Mo film forming module 3 via the first and second vacuum transfer chambers 23 and 24, the W film 12 and the Mo film 13 are formed in the in-situ condition.

In the film forming apparatus 2 shown in FIG. 17, the Mo film forming module 3 may be constituted with the sputtering device in which a target is Mo so that the Mo film 13 is formed by the sputtering method. Further, vacuum degrees of the first vacuum transfer chamber 23 and the second vacuum transfer chamber 24 may be identical to each other.

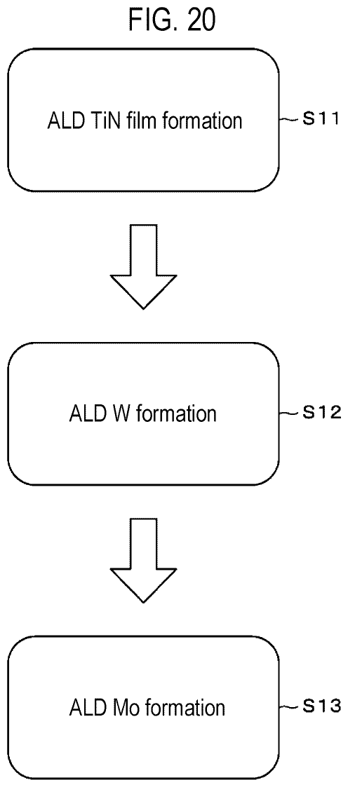

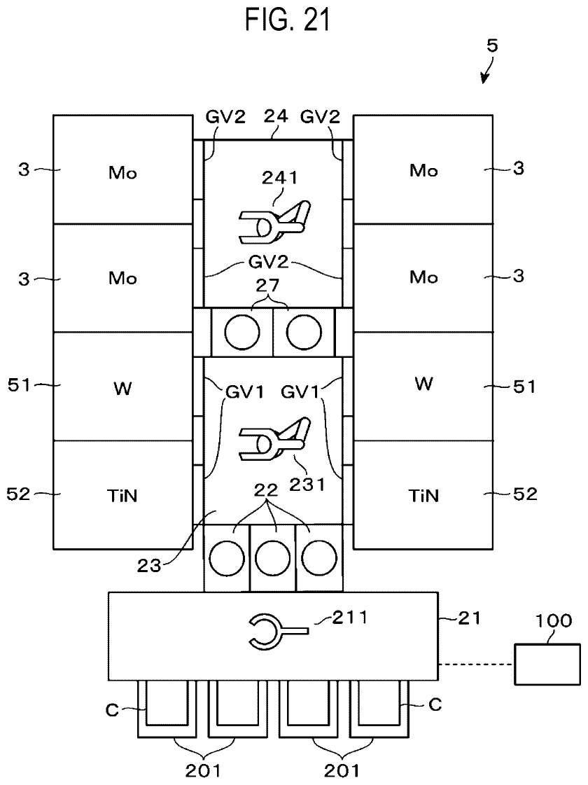

Next, an exemplary configuration of a film forming apparatus 5 for forming the W film 12 and the Mo film 13 in the second embodiment will be described with reference to FIGS. 20 and 21. As illustrated in FIG. 20, the film forming apparatus 5 performs Operation S11 of forming the TiN film 14 on the wafer 10 having the SiO₂ film 11 formed thereon by the ALD method, Operation S12 of forming the W film 12 on the TiN film 14 by the ALD method, and Operation S13 of forming the Mo film 13 on the W film 12 by the ALD method.

Constituent elements of the film forming apparatus 5 illustrated in FIG. 21, which are different from those of the film forming apparatus 2 illustrated in FIG. 17, will be described. In the film forming apparatus 5, a W film forming module 51 constituting the first processing module and a TiN film forming module 52 which forms the TiN film 14 are connected to the first vacuum transfer chamber 23. Further, the Mo film forming module 3 as the second processing module which forms the Mo film 13 by the ALD method is connected to the second vacuum transfer chamber 24. The vacuum degrees of the first vacuum transfer chamber 23 and the second vacuum transfer chamber 24 are identical to each other. Other configurations are similar to those of the film forming apparatus 2 illustrated in FIG. 17, and therefore like constituent elements will be designated by like reference numerals.

The W film forming module 51 and the TiN film forming module 52 are film forming modules configured to perform the film formation by the ALD method. Therefore, the W film forming module 51 is configured such that in the film forming module 3 illustrated in FIG. 19, for example, a tungsten pentachloride gas (WCl₅ gas) is used as the raw material gas, and for example, a H₂ gas is used as the reducing gas.

Further, the TiN film forming module 52 is configured such that in the film forming module 3 illustrated in FIG. 19, for example, a TiCl₄ gas is used as the raw material gas, and for example, a NH₃ gas is used as the nitride gas.

In the film forming apparatus 5 illustrated in FIG. 21, the wafer 10 accommodated in the carrier C is transferred along a route of the atmospheric transfer chamber 21→the load lock chamber 22→the first vacuum transfer chamber 23→the TiN film forming module 52. Further, in the TiN film forming module 52, the TiN film 14 is formed on the wafer 10 by the ALD method.

Subsequently, the wafer 10 is transferred along a route of the first vacuum transfer chamber 23→the W film forming module 51. In the W film forming module 51, the W film 12 is formed on the TiN film 14 by the ALD method.

Subsequently, the wafer 10 is transferred along a route of the first vacuum transfer chamber 23→the deliverer 27→the second vacuum transfer chamber 24→the Mo film forming module 3. In the Mo film forming module 3, the Mo film 13 is formed on the W film 12. Thereafter, the wafer 10 is accommodated in the original carrier C along a route of the second vacuum transfer chamber 24→the deliverer 27→the first vacuum transfer chamber 23→the load lock chamber 22→the atmospheric transfer chamber 21→the carrier C.

Even in this example, since the wafer 10 is transferred from the W film forming module 51 to the Mo film forming module 3 via the first and second vacuum transfer chambers 23 and 24, the W film 12 and the Mo film 13 are formed in the in-situ condition.

However, in the film forming apparatus 5 illustrated in FIG. 21, the TiN film forming module 52 may not be necessarily provided. Further, the W film forming module 51 and the Mo film forming module 3 may be constituted with the sputtering device illustrated in FIG. 18, and each of the W film 12 and the Mo film 13 may be formed by the sputtering method.

In the above, the apparatuses for forming the W film 12 and the Mo film 13 in the first embodiment and the second embodiment may not necessarily have a configuration in which the first processing module and the second processing module are connected to the vacuum transfer chamber, like the film forming apparatuses 2 and 5 described with reference to FIGS. 17 and 21. For example, by using the sputtering device alone illustrated in FIG. 18 and setting a target at one side and a target at the other side to W and Mo, respectively, the first processing module which forms the W film and the second processing module which forms the Mo film may be communalized into a single module. Even in this case, the W film 12 and the Mo film 13 may be formed in the in-situ condition.

In addition, in the case in which the W film 12 and the Mo film 13 are formed by the ALD method, the raw material gas, the reducing gas, and the purge gas are not limited to the above-described examples. Further, layouts of the film forming apparatuses 2 and 5 described above are merely examples, and the film forming apparatuses 2 and 5, the sputtering device illustrated in FIG. 18, or the film forming module illustrated in FIG. 9 is not limited to the above-described configurations.

According to the present disclosure in some embodiments, it is possible to form a molybdenum metal film having a relatively low specific resistance.

The embodiments disclosed herein should be considered to be exemplary and not limitative in all respects. The above embodiments may be omitted, replaced, and modified in various ways without departing from the scope and spirit of the appended claims.

What is claimed is:

1. A method of forming a molybdenum metal film on a substrate, the method comprising:
forming a tungsten metal underlying film on the substrate; and
forming the molybdenum metal film on the tungsten metal underlying film.

2. The method of claim 1, wherein the metal underlying film is stacked on a silicon oxide film or a titanium nitride film, which is formed on the substrate.

3. The method of claim 1, wherein the tungsten metal underlying film is formed by a sputtering method.

4. The method of claim 1, wherein the molybdenum metal film is formed by an ALD method or a sputtering method.

5. The method of claim 4, wherein, when the molybdenum metal film is formed by the ALD method, a raw material gas containing MoO₂Cl₂ is used.

6. The method of claim 4, wherein, when the molybdenum metal film is formed by the ALD method, a raw material gas containing an oxygen-free molybdenum halide is used.

7. The method of claim 1, wherein a film thickness of the tungsten metal underlying film is in a range of 1 nm to 5 nm.

8. An apparatus for forming a molybdenum metal film on a substrate, comprising:
a first processing module configured to form a tungsten metal film on the substrate;
a second processing module configured to form the molybdenum metal film on the substrate; and
a controller,
wherein the controller is configured to output control signals for executing forming a tungsten metal underlying film on the substrate inside the first processing module and forming the molybdenum metal film on the tungsten metal underlying film inside the second processing module.

9. The apparatus of claim 8, further comprising:
a vacuum transfer chamber to which the first processing module and the second processing module are connected; and
a substrate transfer mechanism disposed inside the vacuum transfer chamber,
wherein the controller is configured to output a control signal for executing transferring the substrate from the first processing module to the second processing module via the vacuum transfer chamber between the forming of the tungsten metal underlying film and the forming of the molybdenum metal film.

10. The apparatus of claim 9, wherein the first processing module is configured to form the tungsten metal underlying film by a sputtering method, and the second processing module is configured to form the molybdenum metal film by an ALD method.

11. The apparatus of claim 9, wherein the first processing module is configured to form the tungsten metal underlying film by an ALD method, and the second processing module is configured to form the molybdenum metal film by the ALD method.

12. The apparatus of claim 9, wherein the first processing module is configured to form the tungsten metal underlying film by a sputtering method, the second processing module is configured to form the molybdenum metal film by the sputtering method, and the first processing module and the second processing module are communalized into a single module.
